(19) United States
(12) Patent Application Publication
(10) Pub. No.: US 2010/0003819 A1
(43) Pub. Date: Jan. 7, 2010

(54) DESIGN LAYOUT DATA CREATING METHOD, COMPUTER PROGRAM PRODUCT, AND METHOD OF MANUFACTURING SEMICONDUCTOR DEVICE

(76) Inventors: Takafumi TAGUCHI, Kanagawa (JP); Toshiya KOTANI, Tokyo (JP); Hiromitsu MASHITA, Kanagawa (JP); Fumiharu NAKAJIMA, Kanagawa (JP); Chikaaki KODAMA, Kanagawa (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 12/491,129

(22) Filed: Jun. 24, 2009

(30) Foreign Application Priority Data
Jul. 1, 2008 (JP) 2008-172403

(51) Int. Cl. H01L 21/02; G06F 17/50

(52) U.S. Cl. 438/669; 716/21; 716/8; 257/E21.002; 257/E21.237

(57) ABSTRACT

A design layout data creating method includes creating design layout data of a semiconductor device such that patterns formed on a wafer when patterns corresponding to the design layout data are formed on the wafer have a pattern coverage ratio within a predetermined range in a wafer surface and total peripheral length of the patterns formed on the wafer when the patterns corresponding to the design layout are formed on the wafer is pattern peripheral length within a predetermined range.

### CROSS-REFERENCE TO RELATED APPLICATIONS

This application is based upon and claims the benefit of priority from the prior Japanese Patent Application No. 2008-172403, filed on Jul. 1, 2008; the entire contents of which are incorporated herein by reference.

### BACKGROUND OF THE INVENTION

1. Field of the Invention

The present invention relates to a design layout data creating method, a computer program product, and a method of manufacturing a semiconductor device.

2. Description of the Related Art

In recent years, semiconductor manufacturing technologies have been remarkably advanced. Semiconductor devices in the half-pitch 50 nm generation are mass-produced. Refining of semiconductor devices such as those in the half-pitch 50 nm generation is realized by a remarkable advance in fine-pattern forming technologies such as a mask process technology, a lithography process technology, and an etching process technology. In the age when a size of a pattern formed on a wafer is sufficiently large, a pattern having a shape same as that of a pattern drawn by a designer is formed on a mask as a mask pattern. An exposing device forms a pattern as designed on the wafer by transferring the mask pattern onto a resist applied on the wafer. However, in recent years, the influence of diffraction of exposing light on dimensions on the wafer is becoming large because of refining of a pattern size. Further, mask manufacturing and a wafer process for accurately forming a fine pattern are becoming difficult. Therefore, even if a mask pattern having a pattern shape same as that of a design pattern is used, it is difficult to form a pattern shape as designed on the wafer.

As a method of faithfully forming a pattern having a shape same as that of a design pattern on a wafer, there are methods of subjecting a design pattern on a mask pattern to optical proximity correction (OPC) and process proximity correction (PPC).

As one of technologies of the PPC, a method of arranging a dummy pattern unrelated to circuit operation on a design layout to reduce fluctuation in a process conversion difference for each product (a resist shape after development and a pattern shape after etching) is proposed. The dummy pattern is arranged on a design layout at predetermined density to set a pattern coverage ratio (a pattern forming ratio) within a predetermined range in a wafer surface.

In a pattern designing method disclosed in Japanese Patent Application Laid-Open No. 2006-60051, a dummy pattern forming area is divided into a plurality of dummy pattern forming unit areas and a plurality of inspection ranges having an area larger than that of the dummy pattern forming unit areas are set to partially overlap each other. Provisional pattern coverage ratios of dummy patterns formed in the dummy pattern forming unit areas in the inspection ranges are calculated and the calculated provisional pattern coverage ratios are averaged to calculate a final pattern coverage ratio. Further, dummy patterns having an area equivalent to the final pattern coverage ratio is generated in the dummy pattern forming unit areas as patterns.

However, a pattern having an accurate shape cannot be formed on a wafer only by adjustment of a pattern coverage ratio as in the technologies in the past. This is because a deposit amount and etching time of a sidewall protective film in a machining process (an etching process) are different and a process conversion difference fluctuates because of a difference in an occupancy ratio of cells formed on the wafer. To suppress the fluctuation in the process conversion difference, PPC data has to be taken again to create a mask for each product. Therefore, development turn around time (TAT) increases.

### BRIEF SUMMARY OF THE INVENTION

A design layout data creating method according to an embodiment of the present invention comprises: creating design layout data of a semiconductor device such that patterns formed on a wafer when patterns corresponding to the design layout data are formed on the wafer have a pattern coverage ratio within a predetermined range in a wafer surface and total peripheral length of the patterns formed on the wafer when the patterns corresponding to the design layout are formed on the wafer is pattern peripheral length within a predetermined range.

A computer program product according to an embodiment of the present invention comprises: causing a computer to execute processing for creasing design layout data of a semiconductor device such that patterns formed on a wafer when patterns corresponding to the design layout data are formed on the wafer have a pattern coverage ratio within a predetermined range in a wafer surface and total peripheral length of the patterns formed on the wafer when the patterns corresponding to the design layout are formed on the wafer is pattern peripheral length within a predetermined range.

A method of manufacturing a semiconductor device according to an embodiment of the present invention comprises: forming a pattern corresponding to a design layout data of a semiconductor device on a wafer, the design layout data being created such that patterns formed on the wafer when patterns corresponding to the design layout data are formed on the wafer have a pattern coverage ratio within a predetermined range in a wafer surface and total peripheral length of the patterns formed on the wafer when the patterns corresponding to the design layout are formed on the wafer is pattern peripheral length within a predetermined range.

### BRIEF DESCRIPTION OF THE DRAWINGS

FIG. 1 is a diagram of a configuration of a mask data creating apparatus according to an embodiment of the present invention;

FIG. 2 is a diagram for explaining a mother product and a derived product;

FIGS. 3A and 3B are diagrams for explaining pattern peripheral lengths in one shot of the derived product and the mother product;

FIG. 4 is a diagram for explaining a method of adjusting the pattern peripheral length;

FIG. 5 is a diagram of a manufacturing processing procedure for the mother product;

FIG. 6 is a flowchart of a layout-data creation processing procedure for the derived product;

FIG. 7 is a flowchart of an arrangement processing procedure for dummy patterns registered in a library format; and

FIG. 8 is a diagram of an example of the dummy patterns registered in the library.

### DETAILED DESCRIPTION OF THE INVENTION

Exemplary embodiments of the present invention are explained in detail below. The present invention is not limited by the embodiments.

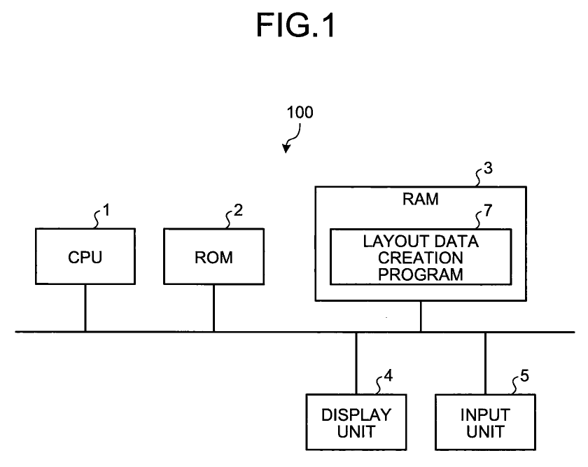

FIG. 1 is a diagram of a configuration of a mask data creating apparatus according to an embodiment of the present invention. A mask data creating apparatus 100 is an apparatus such as a computer that creates design layout data (design data) and mask pattern data of a photomask used for exposure processing of a semiconductor device manufacturing process. The mask data creating apparatus 100 includes a central processing unit (CPU) 1, a read only memory (ROM) 2, a random access memory (RAM) 3, a display unit 4, and an input unit 5. In the mask data creating apparatus 100, the CPU 1, the ROM 2, the RAM 3, the display unit 4, and the input unit 5 are connected via a bus line.

The CPU 1 creates design layout data using a layout data creation program (a pattern design program) 7, which is a computer program for designing design layout data.

The display unit 4 is a display device such as a liquid crystal monitor. The display unit 4 displays, based on instructions from the CPU 1, design layout data, a design drawing, a lithography target, mask data, and the like. The input unit 5 includes a mouse and a keyboard. The input unit 5 inputs instruction information (parameters and the like necessary for creating design layout data) input from the outside by a user. The instruction information input to the input unit 5 is sent to the CPU 1.

The layout data creation program 7 is stored in the ROM 2 and loaded to the RAM 3 via the bus line. The CPU 1 executes the layout data creation program 7 loaded in the RAM 3. Specifically, in the mask data creating apparatus 100, the CPU 1 reads out the layout data creation program 7 from the ROM 2 and expands the layout data creation program 7 in a program storage area in the RAM 3 to execute various kinds of processing according to instruction input from the input unit 5 by the user. The CPU 1 causes the RAM 3 to temporarily store various data generated in the various kinds of processing in a data storage area formed in the RAM 3.

When a photomask is manufactured, first, a prototype (a mother product 10M explained later) of the photomask is manufactured. An actual product (a derived product 10P explained later) is manufactured by using information concerning a pattern of the mother product 10M. Therefore, when design layout data is created, first, design layout data of the mother product 10M is created. Design layout data of the derived product 10P is created by using information concerning a pattern of the mother product 10M. The mother product 10M is a developed product manufactured at a development stage of a semiconductor device. The derived product 10P is a mass-produced product manufactured when the semiconductor device is mass-produced. When the semiconductor device is manufactured, first, a device test elementary group (TEG) or the like is formed in the mother product 10M in advance. Adjustment of design layout data of the derived product 10P is performed by using a pattern coverage ratio and pattern peripheral length obtained from the device TEG and the like.

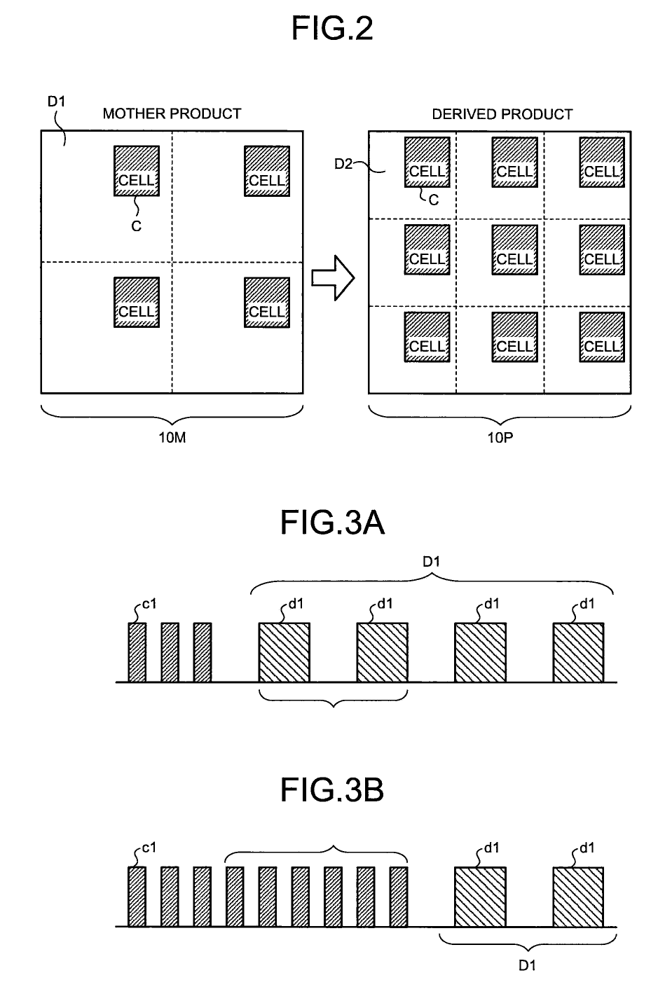

FIG. 2 is a diagram for explaining a mother product and a derived product. One to a plurality of chips are arranged on a photomask of the mother product 10M. One to a plurality of cells (memory cells) are arranged in each of the chips as product patterns. In FIG. 2, four chips are arranged on the photomask of the mother product 10M and one cell C is arranged in each of the chips. To set a pattern coverage ratio in each of the chips within a predetermined range, an area in which a dummy pattern is arranged (a dummy pattern area D1) is provided in an area (e.g., an annular area) in each of the chip other than an area in which a product pattern such as the cell C is arranged.

When design layout data of the mother product 10M is created, a desired circuit pattern such as the cell C is arranged in each of the chips. Thereafter, a predetermined dummy pattern is arranged in the dummy pattern area D1. In this embodiment, a pattern coverage ratio of each of the chips and pattern peripheral length in a wafer surface (a total value of peripheral lengths of patterns) are calculated from the design layout data of the mother product 10M in which dummy patterns are arranged. Design layout data of the derived product 10P (a product mask for mass production) is created by using the calculated pattern coverage ratio and pattern peripheral length. The pattern coverage ratio and the pattern peripheral length in this embodiment are a pattern coverage ratio and pattern peripheral length of a pattern (a shape after etching) to be formed on a wafer. The pattern coverage ratio and the pattern peripheral length can be a pattern coverage ratio and pattern peripheral length on any one of the design layout data, a lithography target explained later, mask data, and a pattern after lithography.

One to a plurality of chips are arranged on a photomask of the derived product 10P. One to a plurality of cells are arranged in each of the chips. In FIG. 2, nine chips are arranged on the photomask of the derived product 10P and one cell C is arranged in each of the chips.

When design layout data of the derived product 10P is created, a desired circuit pattern such as the cell C (a cell area) is arranged in each of the chips. To set a pattern coverage ratio in each of the chips of the derived product 10P to be the same as the pattern coverage ratio of the mother product 10M, a dummy pattern area D2 is provided in an area in each of the chips other than an area in which the cell C is arranged. Dummy patterns corresponding to the pattern coverage ratio and the pattern peripheral length calculated by using the design layout data of the mother product 10M are arranged in the dummy pattern area D2. Consequently, the pattern coverage ratio in each of the chips of the derived product 10P is set to be the same as the pattern coverage ratio in each of the chips of the mother product 10M. Dummy patterns are arranged in the derived product 10P to set total pattern peripheral length in the wafer surface the same when a pattern is formed on the entire wafer by the derived product 10P and when a pattern is formed on the entire wafer by the mother product 10M.

In the derive product 10P and the mother product 10M, because the pattern coverage ratio in the chip is the same, a pattern coverage ratio in a shot (one photomask) is also the same. Therefore, a pattern coverage ratio in the wafer surface is the same in the derived product 10P and the mother product 10M. Further, total pattern peripheral length in the wafer surface is the same in the derived product 10P and the mother product 10M. Consequently, even when the number of shots on the wafer is different in the derived product 10P and the mother product 10M, pattern peripheral length of a pattern formed in the wafer surface is the same in the mother product 10M and the derived product 10P. In the above explanation, the cell is arranged in each of the chips as a product pattern. However, the product pattern arranged in each of the chips can be a pattern other than the cell.

Pattern peripheral lengths in the wafer surfaces of the derived product 10P and the mother product 10M are explained with reference to FIGS. 3A and 3B. For example, even when a pattern having the same pattern coverage ratio is arranged in the wafer surface, pattern peripheral length in the wafer surface increases as an occupancy ratio of the cell C (a cell occupancy ratio) in the wafer surface increases.

In FIGS. 3A and 3B, dummy patterns d1 arranged in the dummy pattern area D1 and cell patterns c1 arranged in the cell C are shown in section. The mother product 10M is shown in FIG. 3A. Four dummy patterns d1 and three cell patterns c1 are arranged in the mother product 10M. The derived product 10P is shown in FIG. 3B. Two dummy patterns d1 and nine cell patterns c1 are arranged in the derived product 10P. Patterns having the same areas are arranged in FIGS. 3A and 3B. A pattern coverage ratio per unit area is the same.

In this case, a cell occupancy ratio (a ratio of the cell C) is larger in FIG. 3B than in FIG. 3A. Therefore, pattern peripheral length in the wafer surface is larger in FIG. 3B than in FIG. 3A. In other words, a larger number of cell patterns c1 having large peripheral length are arranged in FIG. 3B than in FIG. 3A. Therefore, when patterns having the same area are arranged in FIGS. 3A and 3B, a total value (total peripheral length) of pattern peripheral lengths is larger in FIG. 3B than in FIG. 3A. When the pattern peripheral length increases, a surface area of a sidewall section increases. Therefore, a deposit amount of a sidewall protective film per unit area in an etching process decreases. When the deposit amount of the sidewall protective film decreases, side-etch in the etching process tends to occur and a machining shape is deteriorated. When the pattern peripheral length in the wafer surface varies in this way, the deposit amount of the sidewall protective film in the etching process varies and a process conversion difference (a resist shape after development and a pattern shape after etching) fluctuates.

Therefore, in this embodiment, to suppress a difference in the process conversion difference between different products, a design layout of the derived product 10P is created to set a pattern coverage ratio and pattern peripheral length to be the same as those of a mask pattern of the mother product 10M. The mask pattern is created by using OPC same as that for the mother product 10M as OPC (PPC) for the derived product 10P. A pattern (an etching target) that has to be taken into account to suppress a difference in the process conversion difference due to etching is a pattern of the same layer. Therefore, in design layout data (design pattern data), design layout data as a target of adjustment of a coverage ratio and pattern peripheral length is design layout data corresponding to a pattern formed in the same layer on the wafer.

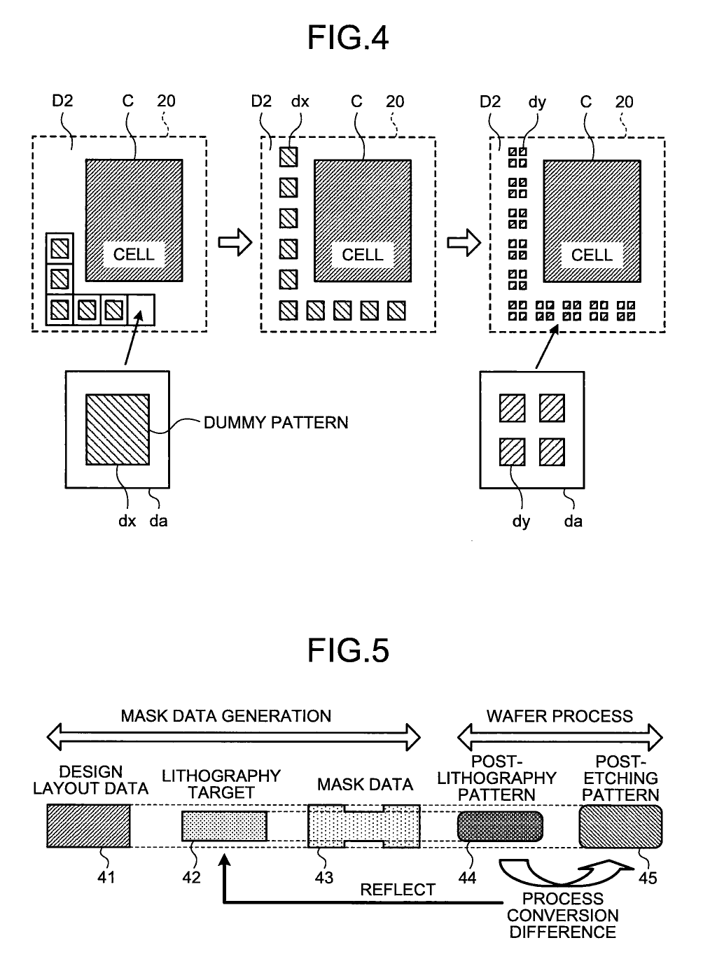

FIG. 4 is a diagram for explaining a method of adjusting pattern peripheral length in creating a mask pattern of the derived product P. The pattern peripheral length is adjusted with respect to a mask pattern of one chip included in the derived product 10P.

In the dummy pattern area D2, a predetermined number of dummy patterns dx having a predetermined area are arranged such that a pattern coverage ratio same as that of the mask pattern of the mother product 10M is obtained. Each of the dummy patterns dx is arranged in a predetermined area (an area da) larger than the dummy pattern dx not to be arranged to overlap the other dummy patterns dx. In the dummy pattern area D2 in a chip 20, areas da in which the dummy patterns dx are arranged are arranged in order such that a mask pattern of the derived product 10P has a pattern coverage ratio same as that of the mask pattern of the mother product 10M.

Thereafter, the dummy patterns dx are divided or integrated in the areas da such that pattern peripheral length in the wafer surface of the derived product 10P is the same as pattern peripheral length in the wafer surface of the mother product 10M. For example, when the pattern peripheral length of the derived product 10P and the pattern peripheral length of the mother product 10M are set the same by reducing the pattern peripheral length of the derived product 10P, a plurality of dummy patterns dx are connected to generate new one dummy pattern. On the other hand, when the pattern peripheral length of the derived product 10P and the pattern peripheral length of the mother product 10M are set the same by increasing the pattern peripheral length of the derived product 10P, new dummy patterns are generated by dividing one dummy pattern dx into a plurality of dummy patterns. In FIG. 4, new dummy patterns dy are generated by dividing one dummy pattern dx into four dummy patterns. The dummy patterns dy generated anew are divided in the area da in which the dummy pattern dx is arranged. This makes it possible to change a layout of a dummy pattern while maintaining a pattern coverage ratio.

FIG. 5 is a diagram of a manufacturing processing procedure for the mother product. To perform pattern formation on a wafer using the mother product 10M, first, mask data generation processing for the mother product 10M is performed. Thereafter, the mother product 10M is manufactured based on mask data of the mother product 10M. Wafer process processing is performed by using the mother product 10M. The mask data generation processing for the mother product 10M is performed by, for example, the mask data creating apparatus 100.

As the mask data generation processing for the mother product 10M, first, layout data (pattern data formed on the wafer) 41 is generated. A lithography target 42 is generated by using the generated design layout data 41. The lithography target 42 is resist pattern data after development necessary for forming a pattern corresponding to the design layout data 41 on the wafer. When the lithography target 42 is generated, the OPC is applied to the lithography target 42 to generate mask data 43 of the mother product 10M.

Thereafter, the mother product 10M is manufactured based on the mask data 43 of the mother product 10M. The wafer process processing is started by using the mother product 10M. As a wafer process, an exposing device performs exposure processing on the wafer, to which a resist is applied, using the mother product 10M. A resist pattern after lithography (a post-lithography pattern 44) is formed on the wafer by developing the wafer. A post-etching pattern 45 is formed on the wafer by etching the wafer on which the post-lithography pattern 44 is formed.

A process conversion difference occurs between the post-lithography pattern 4 (a resist shape after development) and the post-etching pattern 45 (a pattern shape after etching). When the mother product 10M is manufactured, the process conversion difference between post-lithography and post-etching is reflected on the lithography target 42 in advance. Consequently, the pattern shape corresponding to the design layout data and the pattern shape after etching are set the same. The PPC is applied to the lithography target 42 to generate the mask data 43 of the mother product 10M. Thereafter, the mother product 10M is manufactured based on the mask data 43 of the mother product 10M. This makes it possible to manufacture the mother product 10M subjected to the PPC and the OPC. In the following explanation, in some case, OPC correction applied to the lithography target 42 is referred to as OPC for mask and correction performed by combining PPC correction applied to the design layout data 41 and the OPC for mask is referred to as overall OPC correction.

When the derived product 10P is created, the OPC (the PPC) of the mother product 10M, which is used in manufacturing the mother product 10M, is directly used to apply the OPC and the PPC to the lithography target 42 of the derived product 10P. Specifically, first, the design layout data 41 of the derived product 10P is generated. Thereafter, the lithography target 42 of the derived product 10P is generated based on the design layout data 41 of the derived product 10P. The mask data 43 of the derived product 10P is generated by applying the OPC of the mother product 10M to the lithography target 42 of the derived product 10P.

A photomask to be the derived product 10P is manufactured based on the mask data 43 of the derived product 10P. A semiconductor device (a semiconductor integrated circuit) is manufactured by using the derived product 10P in the wafer process. Specifically, exposure processing on the wafer is performed by using the derived product 10P and, thereafter, development processing and etching processing for the wafer are performed. When the semiconductor device is manufactured, the exposure processing, the development processing, and the etching processing are repeated for each layer.

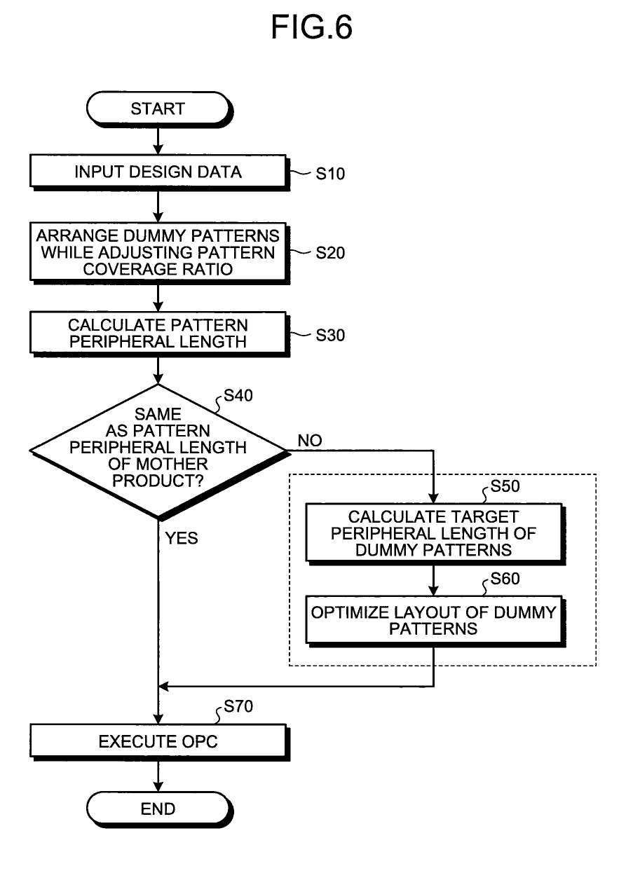

FIG. 6 is a flowchart of a mask data creation processing procedure for the derived product. Before design layout data of the derived product 10P is created, a pattern coverage ratio in the chips (in the wafer surface) of the mother product 10M and pattern peripheral length in the wafer surface are calculated based on the design layout data 41 of the mother product 10M.

When creation of mask data of the derived product 10P is started, the design layout data 41 of the derived product 10P is input to the mask data creating apparatus 100 from the input unit 5 or the like (step S10). The mask data creating apparatus 100 generates the lithography target 42 using the design layout data 41 and generates the mask data 43 corresponding to the lithography target 42. The mask data creating apparatus 100 arranges dummy patterns on the design layout data (the dummy pattern area D2) of the derived product 10P while adjusting a pattern coverage ratio to be the same as that of the design layout data 41 of the mother product 10M (step S20). In other words, the mask data creating apparatus 100 arranges an appropriate dummy pattern on a design layout such that the pattern coverage ratio satisfies a specified value (a value corresponding to the pattern coverage ratio of the mother product 10M). Specifically, the mask data creating apparatus 100 arranges a predetermined number N (N is a natural number) of dummy patterns having a predetermined area on the design layout such that a total area of the dummy patterns and product patterns (cells, etc.) has a predetermined value.

The mask data creating apparatus 100 calculates pattern peripheral length in the wafer surface of the derived product 10P on which the dummy patterns are arranged (step S30). The mask data creating apparatus 100 determines whether the pattern peripheral length in the wafer surface of the derived product 10P is the same as the pattern peripheral length in the wafer surface of the mother product 10M (step S40).

When the pattern peripheral length of the derived product 10P is not the same as the pattern peripheral length of the mother product 10M (“No” at step S40), the mask data creating apparatus 100 calculates target peripheral length of the dummy patterns arranged in the derived product 10P (pattern peripheral length per one dummy pattern). The target peripheral length is a value calculated based on the pattern peripheral length of the mother product 10M (mother peripheral length) and peripheral length of areas other than the dummy patterns of the derived product (cell peripheral length). Specifically, peripheral length of the dummy patterns of the derived product 10P, with which the pattern peripheral length in the wafer surface of the derived product 10P and the pattern peripheral length in the wafer surface of the mother product 10M are the same, is the target peripheral length. When peripheral length of one dummy pattern is set as dummy peripheral length, dummy peripheral length satisfying an equation “mother peripheral length=cell peripheral length+(dummy peripheral length×number of dummies N) is target peripheral length per one dummy pattern arranged in the derived product 10P (step S50). The mother peripheral length, the cell peripheral length, and the number of dummies N are mother peripheral length, cell peripheral length, and the number of dummies N of all patterns arranged in the wafer surfaces.

The mask data creating apparatus 100 optimizes a layout of the dummy patterns based on the calculated target peripheral length of the dummy patterns. Specifically, when total pattern peripheral length of the derived product P in the wafer surface is larger than total pattern peripheral length of the mother product 10M in the wafer surface, the mask data creating apparatus 100 integrates a plurality of dummy patterns to generate new one dummy pattern. On the other hand, when the total pattern peripheral length of the derived product 10P in the wafer surface is smaller than the total pattern peripheral length of the mother product 10M in the wafer surface, the mask data creating apparatus 100 divides one dummy pattern into a plurality of dummy patterns to generate new dummy patterns.

The mask data creating apparatus 100 optimizes the layout of the dummy patterns while keeping a pattern coverage ratio constant. Specifically, the mask data creating apparatus 100 optimizes the layout of the dummy pattern by repeating integration or division of the dummy patterns to set the pattern peripheral length in the wafer surface of the derived product 10P and the pattern peripheral length in the wafer surface of the mother product 10M the same (step S60).

After optimizing the layout of the dummy patterns to set the pattern peripheral length of the derived product 10P and the pattern peripheral length of the mother product 10M the same, the mask data creating apparatus 100 executes the overall OPC on the design layout data 41 of the derived product 10P (step S70). When the pattern peripheral length of the derived product 10P and the pattern peripheral length of the mother product 10M are the same in the wafer surfaces (“Yes” at step S40), the mask data creating apparatus 100 executes the overall OPC on the design layout data 41 of the derived product 10P (step S70).

The design layout data 41 subjected to the overall OPC is taped-out as the mask data 43 of the derived product 10P. The derived product 10P is manufactured by using the mask data 43 subjected to the overall OPC (the PPC and the OPC for mask). In this way, the mask data creating apparatus 100 calculates pattern peripheral length after adjusting a pattern coverage ratio and arranges the dummy patterns on the design layout to create a mask pattern of the derived product 10P to match pattern peripheral length of the mother product 10M subjected to the PPC. The design layout data 41 of the derived product 10P is created for each mask layer necessary for manufacturing of a semiconductor device. The derived product 10P is manufactured for each mask layer necessary for manufacturing of the semiconductor device.

The mask data creating apparatus 100 can replace, in optimizing the layout of the dummy patterns, the present dummy patterns with predetermined dummy patterns prepared in advance without performing creation (division or integration) of dummy patterns.

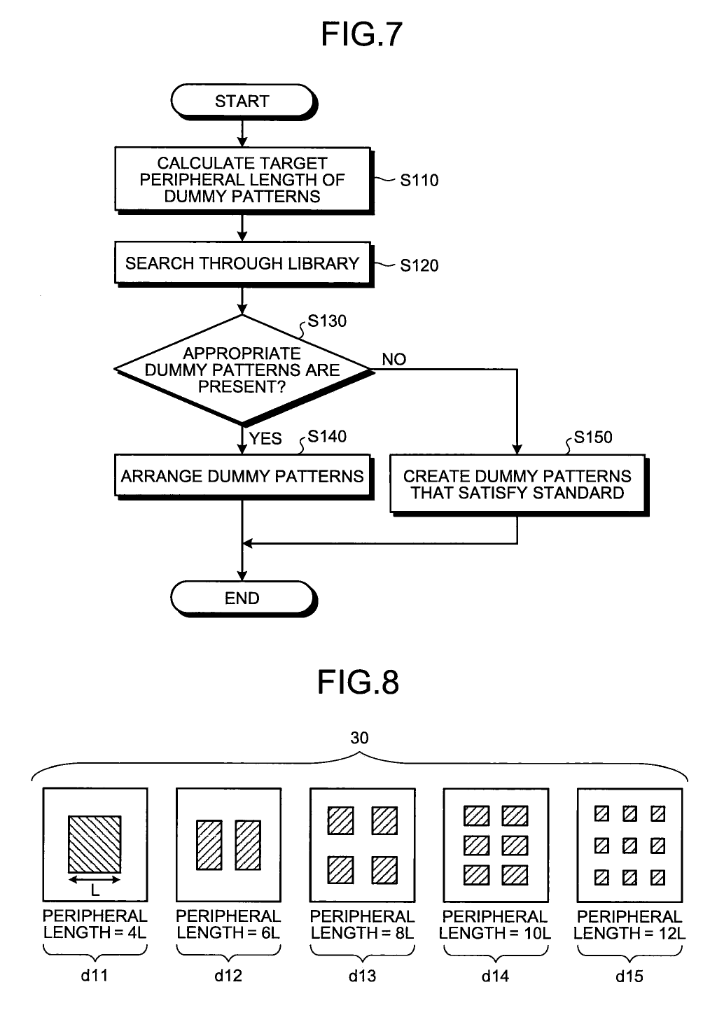

In this case, dummy patterns are registered in the RAM 3 or the ROM 2 in a library format in advance. FIG. 7 is a flowchart of an arrangement processing procedure for the dummy patterns registered in the library format. Processing at steps S110 to S150 shown in FIG. 7 corresponds to the processing at steps S50 and S60 shown in FIG. 6.

When the pattern peripheral length of the derived product 10P is not the same as the pattern peripheral length of the mother product 10M, the mask data creating apparatus 100 calculates target peripheral length of the dummy patterns arranged in the derived product 10P (step S110).

The mask data creating apparatus 100 searches through the library in which the dummy patterns are registered (step S120). FIG. 8 is a diagram of an example of the dummy patterns registered in the library.

In a library 30, dummy patterns having various pattern coverage ratios and various pattern peripheral lengths are registered as a plurality of kinds of dummy patterns. In FIG. 8, five kinds of dummy patterns having the same overage ratios (areas of the dummy patterns are L²) are registered in the library 30. The dummy patterns are dummy patterns having the area L² and pattern peripheral lengths different from one another. Specifically, dummy patterns d11, d12, d13, d14, and d15 having pattern peripheral lengths 4L, 6L, 8L, 10L, and 12L are registered in the library 30.

The dummy patterns d12 having the pattern peripheral length 6L are dummy patterns formed by dividing the dummy pattern d11 having the peripheral length 4L into halves. The dummy patterns d13 having the pattern peripheral length 8L are dummy patterns formed by dividing the dummy pattern d11 having the peripheral length 4L into quarters. The dummy patterns d14 having the pattern peripheral length 10L are dummy patterns formed by dividing the dummy pattern d11 having the peripheral length 4L into one sixths. The dummy patterns d15 having the pattern peripheral length 12L are dummy patterns formed by dividing the dummy pattern d11 having the peripheral length 4L into one ninths.

When the dummy patterns d11 to d15 are created, for example, the dummy patterns d13 are created first. The dummy patterns d11, d12, d14, and d15 are created by dividing and integrating the dummy patterns d13. Examples of the dummy patterns having the area L² are explained with reference to FIG. 8. However, a plurality of kinds of dummy patterns having areas other than L2 are registered in the library 30.

When appropriate dummy patterns (dummy patterns corresponding to the calculated target peripheral length) are present in the library (“Yes” at step S130), the mask data creating apparatus 100 extracts the dummy patterns corresponding to the calculated target peripheral length). When the pattern peripheral length in the wafer surface of the derived product 10P does not satisfy tolerance compared with the pattern peripheral length in the wafer surface of the mother product 10M subjected to the PPC, the mask data creating apparatus 100 can search for other dummy patterns having different pattern peripheral length and satisfying the tolerance from the library. The mask data creating apparatus 100 arranges the extracted dummy patterns in the dummy pattern area of the derived product 10P (step S140). In other words, the mask data creating apparatus 100 replaces the dummy patterns arranged in the derived product 10P at present with the dummy patterns extracted from the library.

On the other hand, when appropriate dummy patterns are not present in the library (“No” at step S130), the mask data creating apparatus 100 creates dummy patterns corresponding to the calculated target peripheral length (dummy patterns satisfying a standard) anew (step S150). The mask data creating apparatus 100 arranges the created dummy patterns in the dummy pattern area of the derived product 10P.

As explained above, in this embodiment, the dummy patterns are arranged on the design layout of the derived product 10P to match the pattern peripheral length in the wafer surface of the mother product 10M subjected to the PPC. Therefore, it is unnecessary to take PPC data for each product again to manufacture the derived product 10P. This makes it possible to easily reduce a difference in a process conversion difference due to a difference in a cell occupancy ratio (pattern peripheral length) of the derived product 10P and reduce development turn around time (TAT) of a photomask (a product).

In this embodiment, the layout data creation program 7 is stored in the ROM 2. However, the layout data creation program 7 can be stored in storage media such as a compact disk (CD) and a hard disk. The layout data creation program 7 can be provided to the mask data creating apparatus 100 via a network such as the Internet.

In this embodiment, the layout of the dummy patterns of the derived product 10P is optimized when the pattern peripheral length of the derived product 10P and the pattern peripheral length of the mother product 10M are not the same. However, the layout of the dummy pattern of the derived product 10P may be optimized when a difference between the pattern peripheral length in the wafer surface of the derived product 10P and the pattern peripheral length in the wafer surface of the mother product 10M is within a predetermined range (within tolerance).

In this embodiment, the pattern coverage ratios in the wafer surfaces are adjusted in the derived product 10P and the mother product 10M and, thereafter, the pattern peripheral lengths in the wafer surfaces are adjusted. However, it is also possible that the pattern peripheral lengths in the wafer surfaces are adjusted and, thereafter, the pattern coverage ratios in the wafer surfaces are adjusted.

In this embodiment, after the dummy patterns are arranged in the derived product 10P, the pattern peripheral lengths in the wafer surfaces are adjusted. However, it is also possible that dummy patterns, pattern coverage ratios and pattern peripheral lengths of which in the wafer surfaces are the same in the derived product 10P and the mother product 10M, are created and, thereafter, the dummy patterns are arranged in the derived product 10P.

As explained above, according to this embodiment, the dummy patterns are arranged on the design layout data 41 of the derived product 10P such that pattern coverage ratios and pattern peripheral lengths on the design layout data 41 in the wafer surfaces are the same in the derived product 10P and the mother product 10M. This makes it possible to use OPC same as that for the mother product 10M as OPC for the derived product 10P. Therefore, it is possible to easily create, in a short time, the design layout data 41 of a photomask (the derived product 10P) with a difference (fluctuation) in a process conversion difference between the derived product 10P and the mother product 10M suppressed. This makes it possible to reduce development TAT of the derived product 10P.

When the layout of the dummy patterns is optimized, the layout is optimized by dividing or integrating the dummy patterns. Therefore, it is possible to optimize the layout of the dummy patterns while easily maintaining the pattern coverage ratio of the derived product 10P. When the layout of the dummy patterns is optimized, the dummy patterns in the library are used. Therefore, it is possible to easily and quickly perform layout of the dummy patterns.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A design layout data creating method comprising creating design layout data of a semiconductor device such that patterns formed on a wafer when patterns corresponding to the design layout data are formed on the wafer have a pattern coverage ratio within a predetermined range in a wafer surface and total peripheral length of the patterns formed on the wafer when the patterns corresponding to the design layout are formed on the wafer is pattern peripheral length within a predetermined range.

2. The design layout data creating method according to claim 1, further comprising, in creating the design layout data, arranging design patterns corresponding to dummy patterns different from product patterns formed in the semiconductor device as design dummy patterns.

3. The design layout data creating method according to claim 2, further comprising, in creating the design layout data, arranging the design dummy patterns such that the patterns formed on the wafer have the pattern coverage ratio within the predetermined range and, thereafter, changing peripheral length of the design dummy patterns while maintaining an area of the design dummy patterns such that total peripheral length of the patterns formed on the wafer is the pattern peripheral length within the predetermined range in the wafer surface.

4. The design layout data creating method according to claim 3, further comprising changing the peripheral length of the design dummy patterns while maintaining the area of the design dummy patterns by dividing or integrating the arranged dummy patterns.

5. The design layout data creating method according to claim 2, further comprising, in creating the design layout data, arranging the design dummy patterns such that the patterns formed on the wafer have the pattern peripheral length within the predetermined range in the wafer surface and, thereafter, changing an area of the design dummy patterns while maintaining peripheral length of the design dummy patterns such that the patterns formed on the wafer have the pattern coverage ratio within the predetermined range in the wafer surface.

6. The design layout data creating method according to claim 2, further comprising arranging the dummy patterns by replacing the dummy patterns with dummy patterns in a library created in advance.

7. A computer program product causing a computer to execute processing for creating design layout data of a semiconductor device such that patterns formed on a wafer when patterns corresponding to the design layout data are formed on the wafer have a pattern coverage ratio within a predetermined range in a wafer surface and total peripheral length of the patterns formed on the wafer when the patterns corresponding to the design layout are formed on the wafer is pattern peripheral length within a predetermined range.

8. The computer program product according to claim 7, further causing the computer to execute processing for, in creating the design layout data, arranging design patterns corresponding to dummy patterns different from product patterns formed in the semiconductor device as design dummy patterns.

9. The computer program product according to claim 8, further causing the computer to execute processing for, in creating the design layout data, arranging the design dummy patterns such that the patterns formed on the wafer have the pattern coverage ratio within the predetermined range and, thereafter, changing peripheral length of the design dummy patterns while maintaining an area of the design dummy patterns such that total peripheral length of the patterns formed on the wafer is the pattern peripheral length within the predetermined range in the wafer surface.

10. The computer program product according to claim 9, further causing the computer to execute processing for changing the peripheral length of the design dummy patterns while maintaining the area of the design dummy patterns by dividing or integrating the arranged dummy patterns.

11. The computer program product according to claim 8, further causing the computer to execute processing for, in creating the design layout data, arranging the design dummy patterns such that the patterns formed on the wafer have the pattern peripheral length within the predetermined range in the wafer surface and, thereafter, changing an area of the design dummy patterns while maintaining peripheral length of the design dummy patterns such that the patterns formed on the wafer have the pattern coverage ratio within the predetermined range in the wafer surface.

12. The computer program product according to claim 8, further causing the computer to execute processing for arranging the dummy patterns by replacing the dummy patterns with dummy patterns in a library created in advance.

13. A method of manufacturing a semiconductor device comprising:
forming a pattern corresponding to a design layout data of a semiconductor device on a wafer, the design layout data being created such that patterns formed on the wafer when patterns corresponding to the design layout data are formed on the wafer have a pattern coverage ratio within a predetermined range in a wafer surface and total peripheral length of the patterns formed on the wafer when the patterns corresponding to the design layout are formed on the wafer is pattern peripheral length within a predetermined range.

14. The method of manufacturing a semiconductor device according to claim 13, further comprising, in creating the design layout data, arranging design patterns corresponding to dummy patterns different from product patterns formed in the semiconductor device as design dummy patterns.

15. The method of manufacturing a semiconductor device according to claim 14, further comprising, in creating the design layout data, arranging the design dummy patterns such that the patterns formed on the wafer have the pattern coverage ratio within the predetermined range and, thereafter, changing peripheral length of the design dummy patterns while maintaining an area of the design dummy patterns such that total peripheral length of the patterns formed on the wafer is the pattern peripheral length within the predetermined range in the wafer surface.

16. The method of manufacturing a semiconductor device according to claim 15, further comprising changing the peripheral length of the design dummy patterns while maintaining the area of the design dummy patterns by dividing or integrating the arranged dummy patterns.

17. The method of manufacturing a semiconductor device according to claim 13, further comprising, in creating the design layout data, arranging the design dummy patterns such that the patterns formed on the wafer have the pattern peripheral length within the predetermined range in the wafer surface and, thereafter, changing an area of the design dummy patterns while maintaining peripheral length of the design dummy patterns such that the patterns formed on the wafer have the pattern coverage ratio within the predetermined range in the wafer surface.

18. The method of manufacturing a semiconductor device according to claim 13, further comprising arranging the dummy patterns by replacing the dummy patterns with dummy patterns in a library created in advance.
